(19) United States
(12) Patent Application Publication
(10) Pub. No.: US 2026/0231467 A1
(43) Pub. Date: Aug. 6, 2026

(54) SEMICONDUCTOR DEVICE

(71) Applicant: POWER MASTER SEMICONDUCTOR CO., LTD., Cheongju-si (KR)

(72) Inventors: Chang Ju LEE, Bucheon-si (KR); Woo Sung PARK, Paju-si (KR)

(21) Appl. No.: 19/194,401

(22) Filed: Apr. 30, 2025

(30) Foreign Application Priority Data
Feb. 4, 2025 (KR) 10-2025-0014035

(51) Int. Cl. H10D 30/66; H01L 21/04; H10D 30/01; H10D 62/10; H10D 62/832

(52) U.S. Cl. CPC H10D 30/662; H10D 30/0291; H10D 62/107; H10P 30/2042; H10P 30/222; H10D 62/8325

(57) ABSTRACT

A semiconductor device and a manufacturing method of the same are provided. The semiconductor device includes an epitaxial layer having a first conductivity type, a first well formed on the upper portion of the epitaxial layer and having a second conductivity type different from the first conductivity type, a second well formed on the upper portion of the epitaxial layer and spaced apart from the first well and having the second conductivity type, and a junction field-effect transistor (JFET) region formed between the first well and the second well, the lower surface of which is formed lower than the lower surface of the first well and the lower surface of the second well.

### CROSS-REFERENCE TO RELATED APPLICATION

This application claims priority to and the benefit of Korean Patent Application No. 10-2025-0014035 filed at the Korean Intellectual Property Office on Feb. 4, 2025, the entire contents of which are incorporated herein by reference.

### BACKGROUND

### (a) Technical Field

The present disclosure relates to a semiconductor device.

### (b) Description of the Related Art

In electric power conversion and power control systems, electric power semiconductor devices have been developed in the form of metal-oxide-semiconductor field-effect transistors (MOSFETs), insulated gate bipolar transistors (IGBTs), diodes, etc., and are widely used in power conversion devices, electric vehicles, renewable energy systems, and high-frequency switching devices. However, silicon semiconductors have a narrow bandgap, low thermal conductivity, and a limited breakdown voltage, which limit their performance in high-voltage and high-temperature environments. Accordingly, wide bandgap semiconductors are gaining attention, with silicon carbide (SiC) and gallium nitride (GaN) being typically used. SiC MOSFETs are developed to overcome the limitations of existing silicon-based MOSFETs and have characteristics such as a wide bandgap, high critical electric field, and excellent thermal conductivity.

### SUMMARY

The present disclosure attempts to provide a semiconductor device capable of reducing cell pitch in a silicon carbide metal-oxide-semiconductor field-effect transistor (SiC MOSFET) to reduce on-resistance, minimizing on/off energy loss that occurs during switching operation, and withstanding short-circuit situations for a longer time than conventional structures.

A semiconductor device according to an embodiment includes an epitaxial layer having a first conductivity type, a first well formed on an upper portion of the epitaxial layer and having a second conductivity type different from the first conductivity type, a second well formed on the upper portion of the epitaxial layer and spaced apart from the first well and having the second conductivity type, and a junction field-effect transistor (JFET) region formed between the first well and the second well, a lower surface of which is formed lower than the lower surface of the first well and the lower surface of the second well.

In some embodiments, the JFET region may be formed to be spaced apart from the first well and the second well.

In some embodiments, the semiconductor may include a first intermediate region defined on the epitaxial layer between the first well and the JFET region, and a second intermediate region defined on the epitaxial layer between the second well and the JFET region.

In some embodiments, the width of the JFET region may be smaller than the distance between the first well and the second well, and greater than the width of the first intermediate region or the second intermediate region.

In some embodiments, the JFET region may not be formed in the lower portion of the first well and the second well.

In some embodiments, the width of the JFET region may be equal to the distance between the first well and the second well, and the JFET region may not be formed in the lower portion of the first well and the second well.

In some embodiments, the width of the JFET region may be greater than the distance between the first well and the second well, and at least a portion of the JFET region may be formed on the lower portion of the first well and the second well.

In some embodiments, the upper surface of the JFET region may be formed lower than the upper surface of the epitaxial layer.

In some embodiments, the JFET region may be formed through a channeling implant performed by tilting a wafer on which photoresists are formed at spacings smaller than the distance between the first well and the second well by a predetermined angle.

In some embodiments, the predetermined angle may be 3 degrees or more and 5 degrees or less.

A manufacturing method of a semiconductor according to an embodiment includes forming an epitaxial layer having a first conductivity type, forming a first well having a second conductivity type different from the first conductivity type on the upper portion of the epitaxial layer, and a second well spaced apart from the first well and having the second conductivity type, and forming a junction field-effect transistor (JFET) region between the first well and the second well such that the lower surface thereof is lower than the lower surface of the first well and the lower surface of the second well.

In some embodiments, the forming of the JFET region may include tilting a wafer on which photoresists are formed at spacings smaller than the distance between the first well and the second well by a predetermined angle and performing a channeling implant.

In some embodiments, the predetermined angle may be 3 degrees or more and 5 degrees or less.

In some embodiments, the JFET region may be formed to be spaced apart from the first well and the second well.

In some embodiments, a first intermediate region may be defined on the epitaxial layer between the first well and the JFET region, and a second intermediate region may be defined on the epitaxial layer between the second well and the JFET region.

In some embodiments, the width of the JFET region may be smaller than the distance between the first well and the second well, and greater than the width of the first intermediate region or the second intermediate region.

In some embodiments, the JFET region may not be formed in the lower portion of the first well or the second well.

In some embodiments, the width of the JFET region may be equal to the distance between the first well and the second well, and the JFET region may not be formed in the lower portion of the first well or the second well.

In some embodiments, the width of the JFET region may be greater than the distance between the first well and the second well, and at least a portion of the JFET region may be formed on the lower portion of the first well and the second well.

In some embodiments, the upper surface of the JFET region may be formed lower than the upper surface of the epitaxial layer.

### BRIEF DESCRIPTION OF THE DRAWINGS

FIG. 1 is a drawing for describing a semiconductor device according to an embodiment.

FIGS. 2 to 22 are drawings for describing a manufacturing method of a semiconductor device according to an embodiment.

FIG. 23 is a drawing for describing a semiconductor device according to an embodiment.

FIG. 24 is a drawing for describing a semiconductor device according to an embodiment.

### DETAILED DESCRIPTION

The present disclosure will be described in detail hereinafter with reference to the accompanying drawings, in which embodiments of the present disclosure are shown. As those skilled in the art would realize, the described embodiments may be modified in various different ways, all without departing from the spirit or scope of the present disclosure. The drawings and description are to be regarded as illustrative in nature and not restrictive, and like reference numerals designate like elements throughout the specification.

Throughout the present specification, unless explicitly stated to the contrary, the word “comprise” and variations such as “comprises” and “comprising” should be understood to imply the inclusion of stated elements but not the exclusion of any other elements.

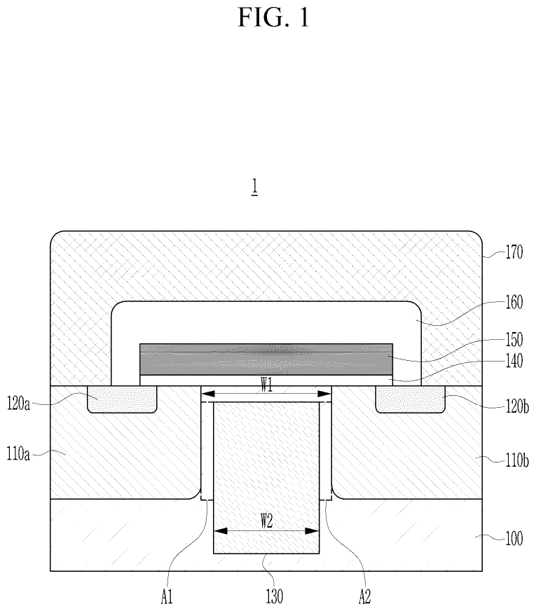

FIG. 1 is a drawing for describing a semiconductor device according to an embodiment.

Referring to FIG. 1, a semiconductor device 1 according to an embodiment may include an epitaxial layer 100, wells 110a and 110b, conductive regions 120a and 120b, a JFET region 130, a gate oxide layer 140, a polysilicon layer 150, a field oxide layer 160, and a metal layer 170.

The epitaxial layer 100 is a monocrystalline semiconductor layer formed on a semiconductor substrate, and may have a first conductivity type. For example, the epitaxial layer 100 may be a low-concentration n-type epitaxial layer formed on the semiconductor substrate and may function as a drift region of the semiconductor device 1. The thickness and doping concentration of the epitaxial layer 100 may be designed in consideration of the breakdown voltage of the target semiconductor device 1, etc.

The wells 110a and 110b are formed on the upper portion of the epitaxial layer 100 and may have a second conductivity type different from the first conductivity type. For example, the wells 110a and 110b may be formed as p-wells. As illustrated, the wells 110a and 110b may include a first well 110a and a second well 110b formed to be spaced apart from the first well 110a.

The conductive regions 120a and 120b are formed inside the wells 110a and 110b and may have the first conductivity type. For example, the conductive regions 120a and 120b may have an n+type. The conductive regions 120a and 120b may correspond to a portion in the semiconductor device 1 where a channel is formed in which electron movement is activated or blocked depending on the gate voltage.

The junction field-effect transistor (JFET) region 130 may be formed between the first well 110a and the second well 110b. Specifically, the JFET region 130 is formed between the first well 110a and the second well 110b, and the lower surface thereof may be formed lower than the lower surface of the first well 110a and the lower surface of the second well 110b.

The JFET region 130 may be formed to be spaced apart from the first well 110a and the second well 110b. As illustrated, intermediate regions A1 and A2 may be defined in the semiconductor device 1. The first intermediate region A1 may be a region defined on the epitaxial layer 100 between the first well 110a and the JFET region 130, and the second intermediate region A2 may be a region defined on the epitaxial layer 100 between the second well 110b and the JFET region 130. Additionally, a width W2 of the JFET region 130 may be smaller than a distance W1 between the first well 110a and the second well 110b and larger than the width of the first intermediate region A1 or the second intermediate region A2. Additionally, the upper surface of the JFET region 130 may be formed lower than the upper surface of the epitaxial layer 100.

The JFET region 130 may be formed only between the first well 110a and the second well 110b. In other words, the JFET region 130 may not be formed on the lower portion of the first well 110a or the second well 110b.

In some embodiments, the JFET region 130 may be formed through a channeling implant performed by tilting a wafer on which photoresists are formed at spacings smaller than the distance W1 between the first well 110a and the second well 110b by a predetermined angle.

The channeling implant may be used for doping to a deeper location than the typical implantation process during ion implantation. For example, in crystalline materials such as silicon, the lattice structure is aligned in a certain direction, so the spacing between atoms in a certain direction may be relatively wider. Ion implantation in this direction allows ions to be implanted deeply through channels between the lattices, allowing for deep doping. In this case, the wafer may be tilted at a specific angle during ion implantation to control the degree to which the ions penetrate through the lattice.

In some embodiments, the predetermined angle may be 3 degrees or more and 5 degrees or less. The channeling implant may also be used to suppress ions from penetrating between lattices depending on the angle at which the wafer is tilted. However, since the JFET region 130 according to the embodiments must be formed lower—that is, deeper—than the lower surface of the first well 110a and the lower surface of the second well 110b, the JFET region 130 may be formed by adopting a tilting angle of 3 degrees or more and 5 degrees or less. In some embodiments, the predetermined angle may be 4 degrees.

The gate oxide layer 140, the polysilicon layer 150, the field oxide layer 160, and the metal layer 170 may be formed on the upper surface of the epitaxial layer 100 in which the JFET region 130 is defined, on the upper surface of the wells 110a and 110b, and on the upper surface of the conductive regions 120a and 120b.

The gate oxide layer 140 may have a function of forming a channel using an electric field effect with an insulating layer between the gate electrode and the channel, and may be formed over a portion of the upper surface of the first conductive region 120a, a portion of the upper surface of the first well 110a, a portion of the upper surface of the epitaxial layer 100, a portion of the upper surface of the second well 110b, and a portion of the upper surface of the second conductive region 120b. The gate oxide layer 140 may include, for example, silicon oxide (SiO₂) or a high-k material.

The polysilicon layer 150 may be formed on the gate oxide layer 140 as a conductive layer used as a gate electrode. The polysilicon layer 150 may include, for example, doped polysilicon and may control current by transmitting a gate signal to the channel.

The field oxide layer 160 has an insulating function and may be formed on a portion of the upper surfaces of the first conductive region 120a and the second conductive region 120b and on the upper surface of the polysilicon layer 150.

The metal layer 170 is a conductive layer forming an electrode and may include, for example, a metal such as aluminum (Al), nickel (Ni), or titanium (Ti).

According to the present embodiment, the JFET region 130 is formed at a higher concentration than the lower surface of the first well 110a and the lower surface of the second well 110b. Accordingly, by minimizing the distance W1 between the first well 110a and the second well 110b, while forming the JFET region 130 sufficiently deep and with a high concentration downward between the first well 110a and the second well 110b, it is possible to prevent an increase in the resistance of the JFET region due to a decrease in the distance W1, thereby securing low on-resistance. In addition, as the width of the JFET region 130 is optimized, the value of a gate-drain capacitance C_{GD} may be reduced, thereby minimizing on/off energy loss and providing a semiconductor device capable of withstanding a short-circuit situation for a longer time than conventional structures.

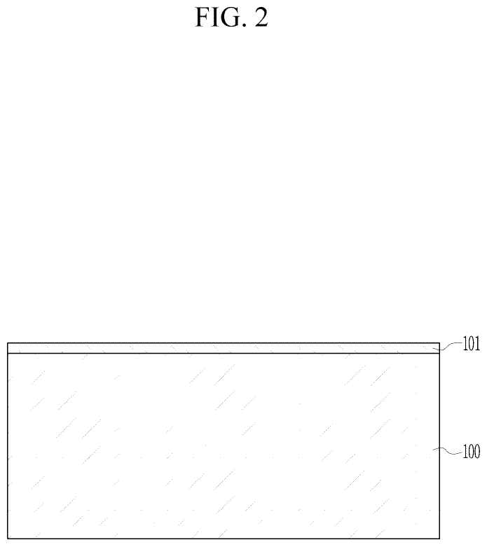

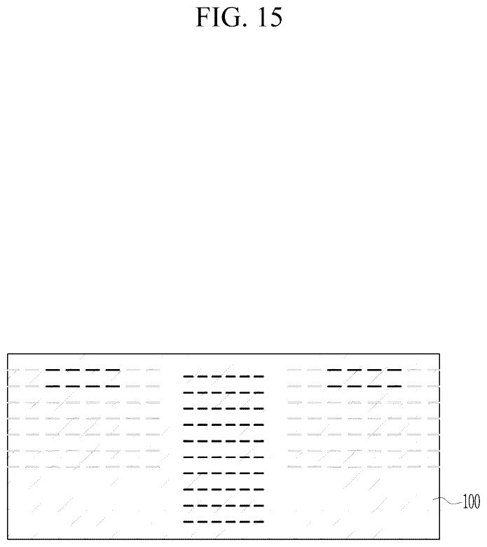

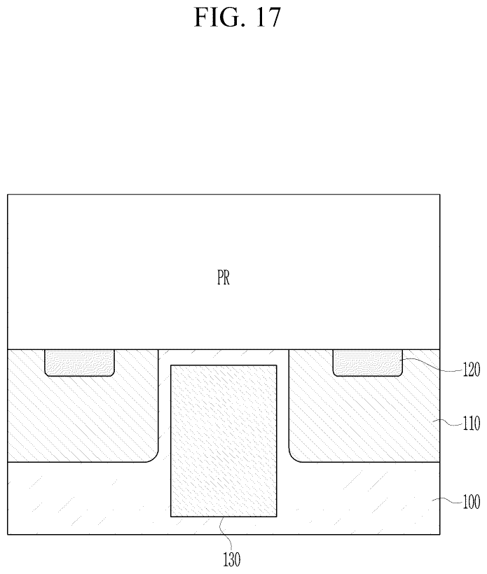

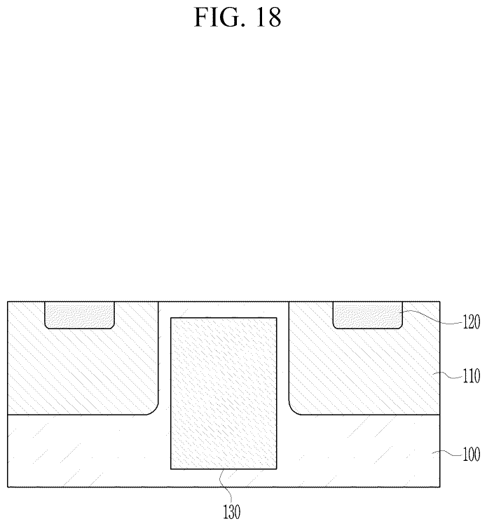

FIGS. 2 to 22 are drawings for describing a manufacturing method of a semiconductor device according to an embodiment.

Referring to FIG. 2, the epitaxial layer 100 having the first conductivity type may be formed. The epitaxial layer 100 is formed on the semiconductor substrate using a monocrystalline growth method, and may be implemented as a semiconductor layer of the first conductivity type doped at a low concentration. A buffer oxide layer 101 may be formed on the epitaxial layer 100. The buffer oxide layer 101 is an insulating layer formed on the epitaxial layer 100 and may protect the epitaxial layer 100 during an ion implantation or deposition process in a subsequent process. In some embodiments, the buffer oxide layer 101 may be formed of silicon oxide (SiO₂) or silicon nitride (SiN) and may be formed using a thermal oxidation or chemical vapor deposition (CVD) process.

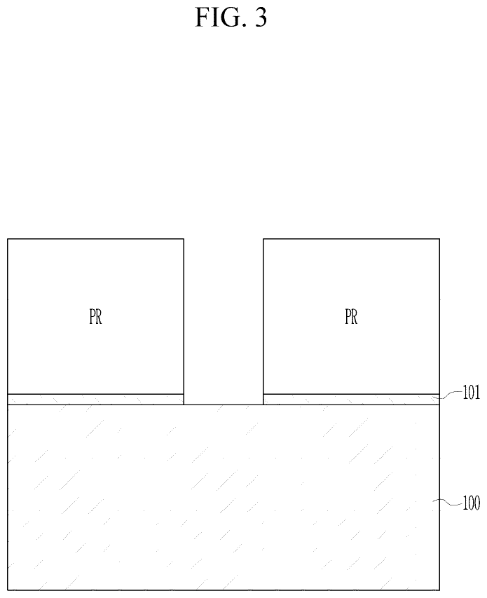

Referring to FIG. 3, photoresists PR may be formed at a predetermined spacing on the buffer oxide layer 101. The photoresist PR is a photosensitive material that can be selectively removed in response to a light source such as ultraviolet or extreme ultraviolet light, and may function as a mask for patterning. Next, the buffer oxide layer 101 may be selectively etched using the photoresist PR as a mask. Wet or dry etching methods may be used, and after etching is completed, the remaining photoresist PR may be removed.

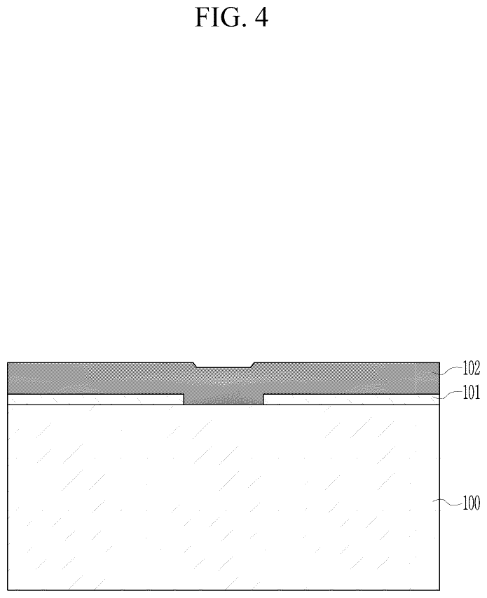

Referring to FIG. 4, a buffer polysilicon layer 102 may be formed on the buffer oxide layer 101 and epitaxial layer 100 on which etching is completed. The buffer polysilicon layer 102 may protect the region where the JFET region 130 will be formed in a subsequent process and control diffusion in the ion implantation process. The buffer polysilicon layer 102 may be deposited, for example, using a low-pressure chemical vapor deposition (LPCVD) process.

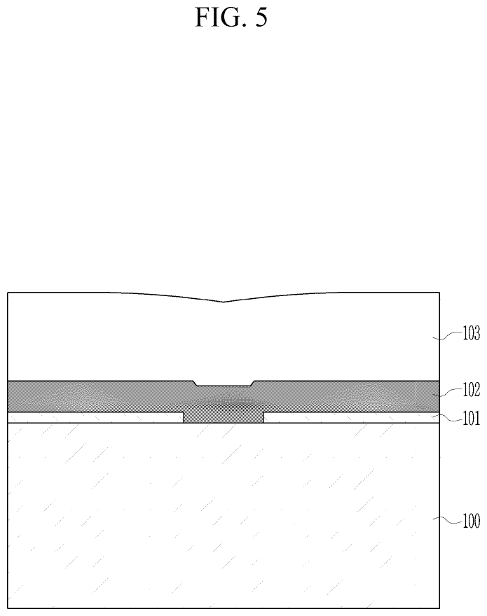

Referring to FIG. 5, a well-forming oxide layer 103 may be formed on the buffer polysilicon layer 102. The well-forming oxide layer 103 may define a well 110 after etching through a subsequent process. That is, the well-forming oxide layer 103 may act as a mask in the subsequent ion implantation process to ensure that p-type impurities are implanted only in specific regions.

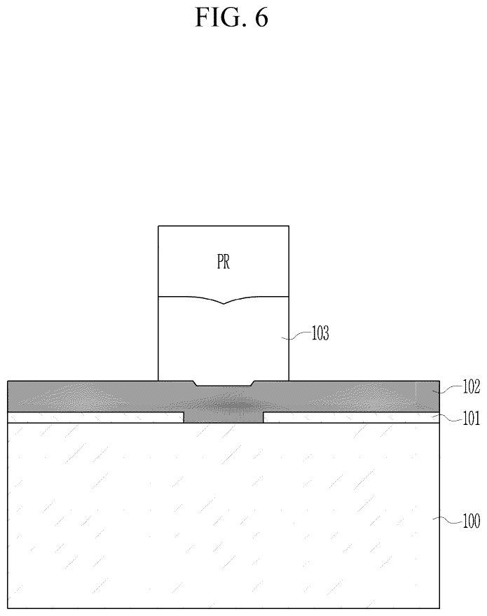

Referring to FIG. 6, the photoresist PR is formed on the well-forming oxide layer 103, and the photoresist PR may be used as a mask to selectively etch the well-forming oxide layer 103.

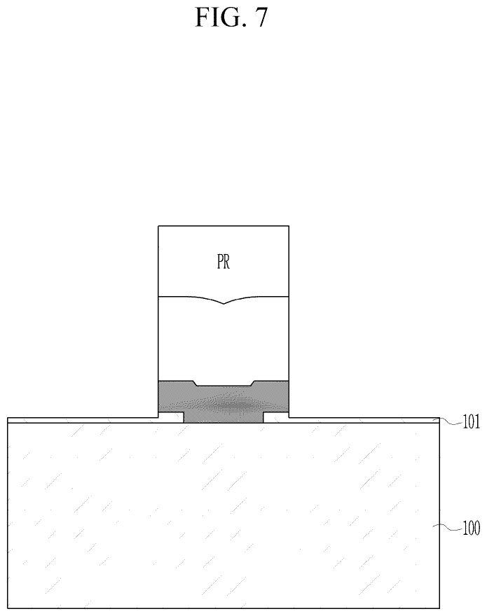

Referring to FIG. 7, the buffer polysilicon layer 102 may then be selectively removed through etching to expose the buffer oxide layer 101. Specifically, the region corresponding to the lower portion of the well-forming oxide layer 103 among the buffer polysilicon layer 102 may be left, and the buffer polysilicon layer 102 may be removed from a region not corresponding to the lower portion of the well-forming oxide layer 103. In this case, a part of the buffer oxide layer 101 is also removed, so that the thickness in a removed region may be reduced.

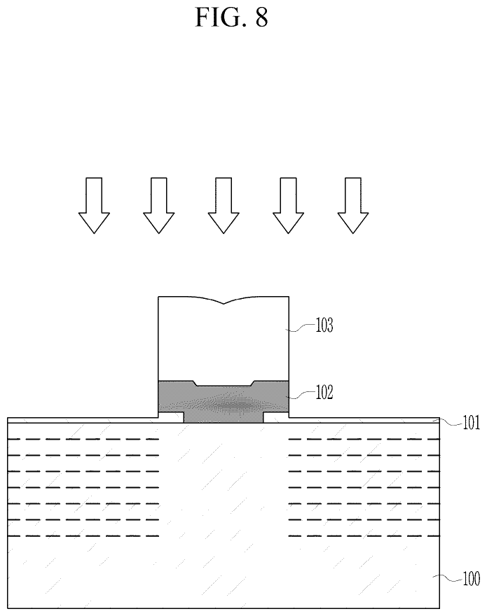

Referring to FIG. 8, after the remaining photoresist PR is removed, ion implantation may be performed to form the well 110. For example, a p-type impurity may be implanted into the epitaxial layer 100 to form a p-well.

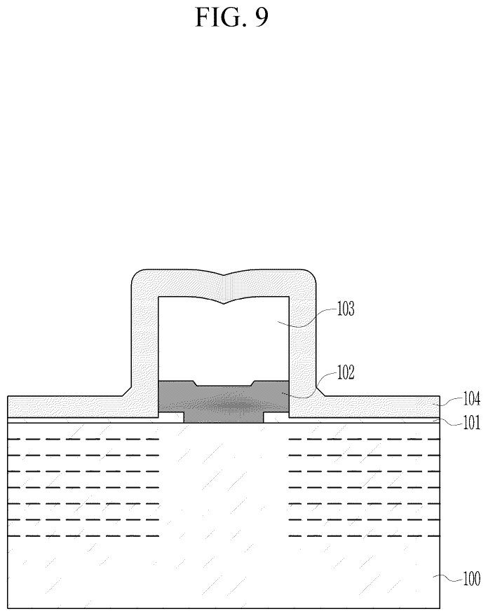

Referring to FIG. 9, after the implantation is completed, a poly spacer 104 may be formed along the upper surface of the exposed buffer oxide layer 101 and the upper surface of the well-forming oxide layer 103. The poly spacer 104 may be formed of silicon oxide (SiO₂) or silicon nitride (SiN), and may be formed through a deposition process.

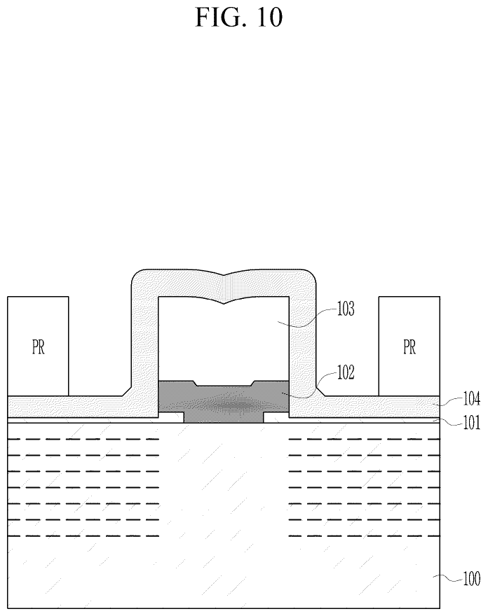

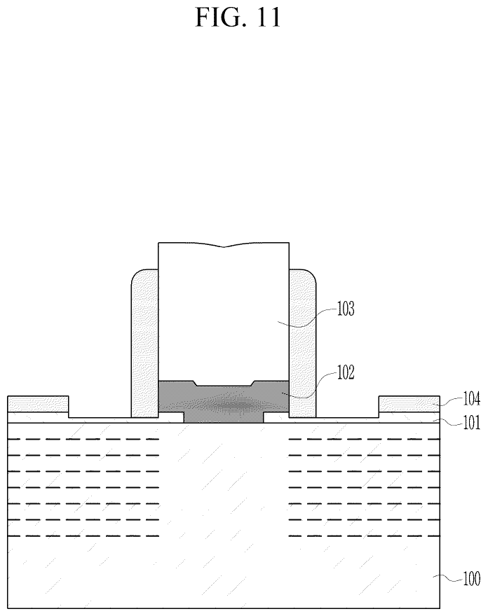

Referring to FIGS. 10 and 11, the photoresist PR is formed on the poly spacer 104, and the poly spacer 104 may be selectively etched using the photoresist PR as a mask. In this case, a part of the buffer oxide layer 101 is also removed, so that the thickness in the removed region may be reduced. Additionally, any remaining photoresist PR may be removed.

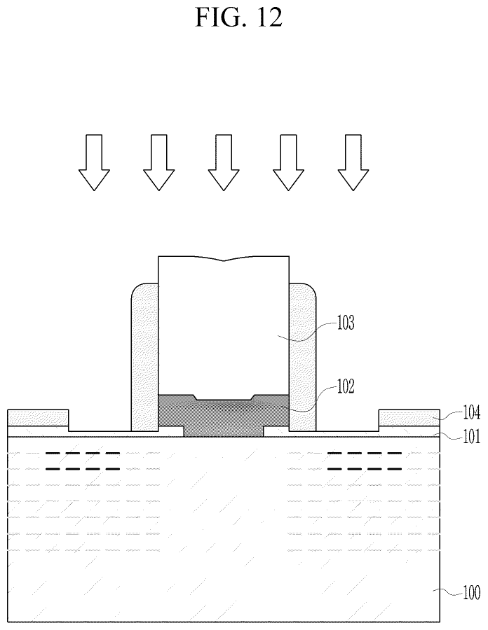

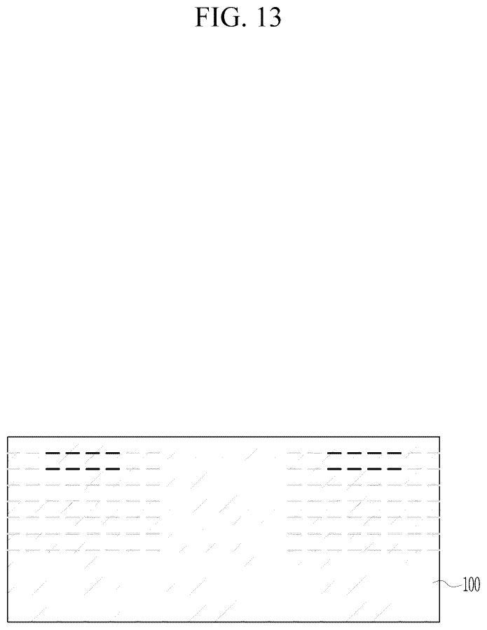

Referring to FIGS. 12 and 13, ion implantation may be performed to form a conductive region 120. For example, an n-type dopant may be implanted into the well 110—the p-well—to form an n+ type conductive region. After the implantation is completed, the remaining buffer oxide layer 101, buffer polysilicon layer 102, well-forming oxide layer 103, and poly spacer 104 may all be removed.

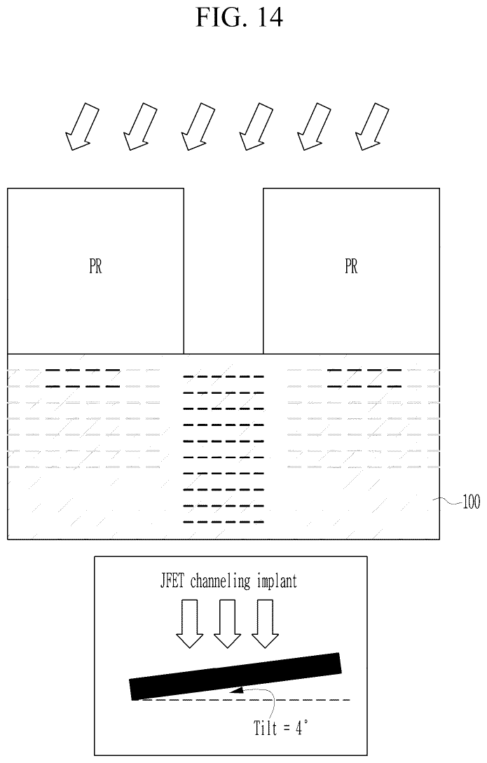

Referring to FIGS. 13 to 15, the photoresists PR may be formed at a predetermined spacing on the epitaxial layer 100 in which ion implantation has been completed. The photoresists PR may be formed to have a predetermined spacing to form the JFET region 130 with a desired depth and width. Additionally, the channeling implant may be performed by tilting the wafer at a specific angle to allow impurities to penetrate between the lattices, allowing for deep implantation. In some embodiments, the predetermined angle may be 3 degrees or more and 5 degrees or less. FIG. 14 illustrates an example where the wafer is tilted at 4 degrees. After the channeling implant is completed, the photoresist PR may be removed. That is, ions implanted into the channeling implant may be injected into the epitaxial layer 100 to penetrate deeper than the implanted depth to form a p-well.

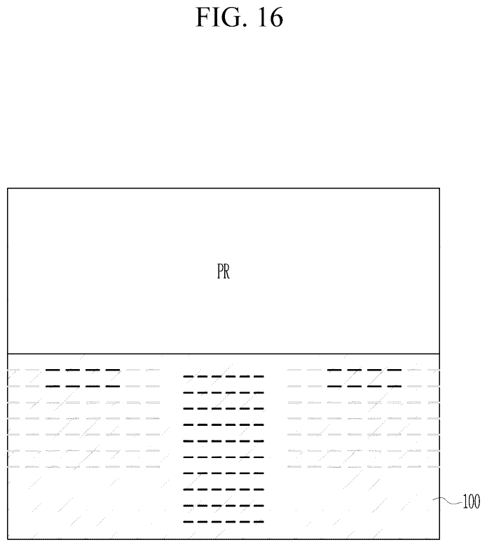

Referring to FIGS. 16 to 18, the photoresist PR is formed on the epitaxial layer 100 on which the channeling implant is completed, and, for example, the implanted impurities may be activated and the well region may be uniformly diffused through a high-temperature annealing process. Accordingly, the well 110 having the second conductivity type different from the first conductivity type, the conductive region 120 having the first conductivity type, and the JFET region 130 may be formed on the upper portion of the epitaxial layer 100. After activation is complete, the photoresist PR may be removed.

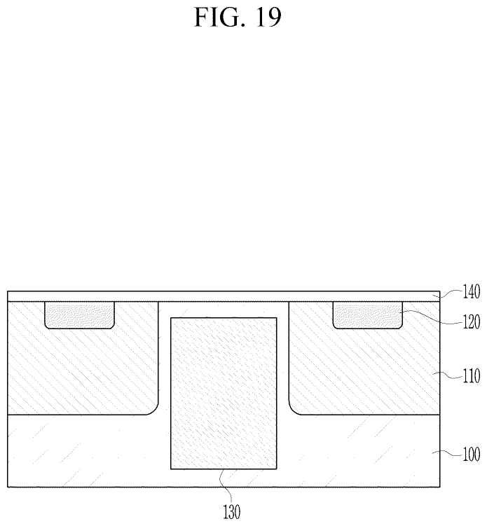

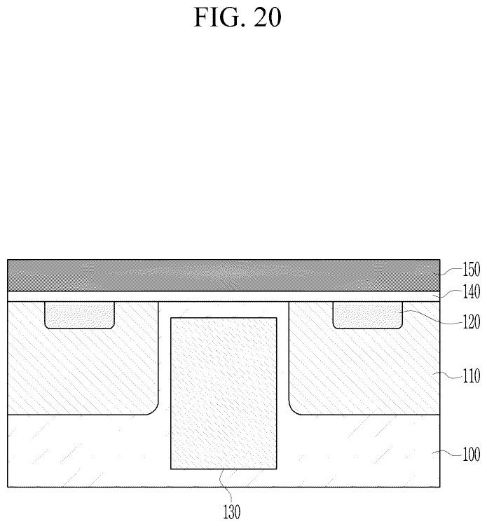

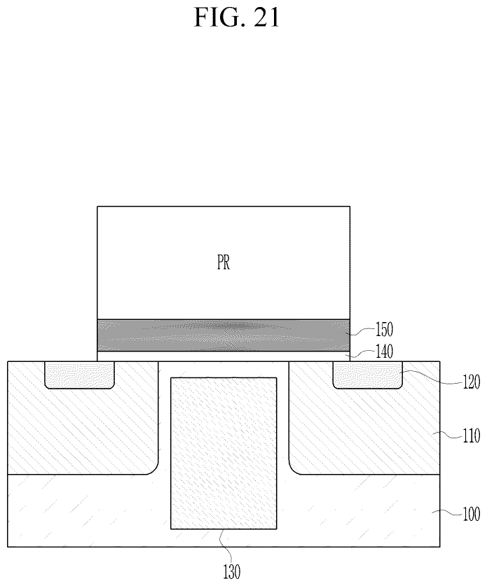

Referring to FIGS. 19 and 20, the gate oxide layer 140 and the polysilicon layer 150 are then formed, and referring to FIG. 21, the gate oxide layer 140 and the polysilicon layer 150 may be selectively removed through an etching process using the photoresist PR as a mask.

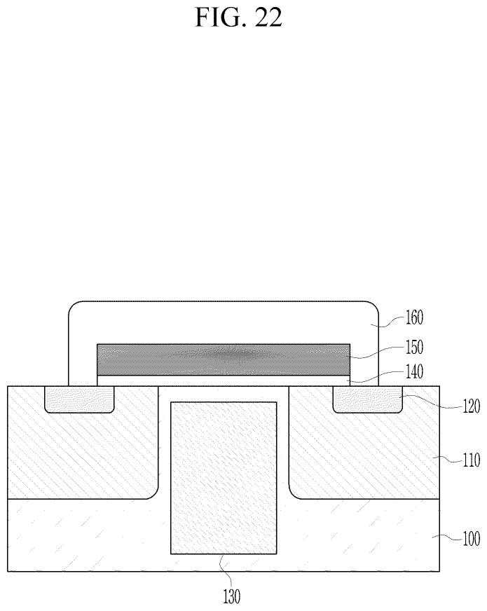

Referring to FIG. 22, after the photoresist PR is removed, the field oxide layer 160 may be formed on the gate oxide layer 140 and the polysilicon layer 150, and the metal layer 170 may be formed on the field oxide layer 160.

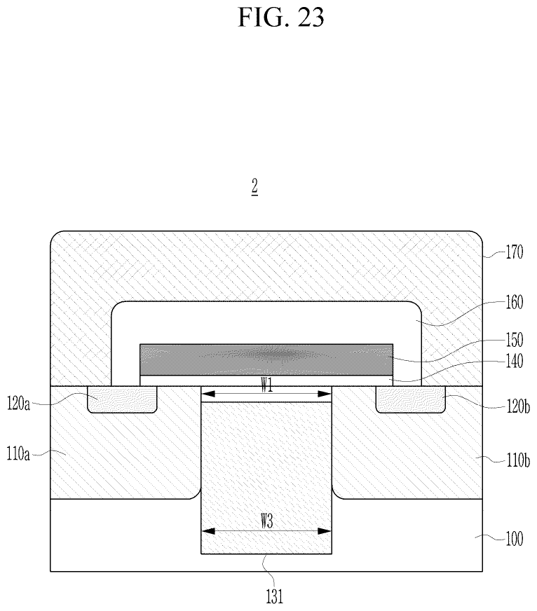

FIG. 23 is a drawing for describing a semiconductor device according to an embodiment.

Referring to FIG. 23, a semiconductor device 2 according to an embodiment may include the epitaxial layer 100, the wells 110a and 110b, the conductive regions 120a and 120b, a JFET region 131, the gate oxide layer 140, the polysilicon layer 150, the field oxide layer 160, and the metal layer 170.

The epitaxial layer 100 is a monocrystalline semiconductor layer formed on the semiconductor substrate and may have the first conductivity type. For example, the epitaxial layer 100 may be a low-concentration n-type epitaxial layer formed on the semiconductor substrate and may function as a drift region of the semiconductor device 1. The thickness and doping concentration of the epitaxial layer 100 may be designed in consideration of the breakdown voltage of the target semiconductor device 1, etc.

The wells 110a and 110b are formed on the upper portion of the epitaxial layer 100 and may have a second conductivity type different from the first conductivity type. For example, the wells 110a and 110b may be formed as p-wells. As illustrated, the wells 110a and 110b may include a first well 110a and a second well 110b formed to be spaced apart from the first well 110a.

The conductive regions 120a and 120b are formed inside the wells 110a and 110b and may have the first conductivity type. For example, the conductive regions 120a and 120b may have an n+type. The conductive regions 120a and 120b may correspond to a portion in the semiconductor device 1 where a channel is formed in which electron movement is activated or blocked, depending on the gate voltage.

The JFET region 131 may be formed between the first well 110a and the second well 110b. Specifically, the JFET region 130 is formed between the first well 110a and the second well 110b, and the lower surface thereof may be formed lower than the lower surface of the first well 110a and the lower surface of the second well 110b.

A width W3 of the JFET region 131 may be formed to be equal to the distance W1 between the first well 110a and the second well 110b. Therefore, unlike the semiconductor device 1 of FIG. 1, no intermediate region is defined between the first well 110a and the JFET region 131 and between the second well 110b and the JFET region 131. Additionally, the upper surface of the JFET region 131 may be formed lower than the upper surface of the epitaxial layer 100.

The JFET region 131 may be formed only between the first well 110a and the second well 110b. In other words, the JFET region 131 may not be formed on the lower portion of the first well 110a or the second well 110b.

In some embodiments, the JFET region 131 may be formed through the channeling implant described with respect to FIG. 1, and the spacing of the photoresist may be arranged differently from the case of forming the JFET region 130 of FIG. 1 to secure the width W3 of the JFET region 131.

The gate oxide layer 140, the polysilicon layer 150, the field oxide layer 160, and the metal layer 170 may be formed on the upper surface of the epitaxial layer 100 in which the JFET region 131 is defined, on the upper surface of the wells 110a and 110b, and on the upper surface of the conductive regions 120a and 120b.

The gate oxide layer 140 may have a function of forming a channel using an electric field effect with an insulating layer between the gate electrode and the channel, and may be formed over a portion of the upper surface of the first conductive region 120a, a portion of the upper surface of the first well 110a, a portion of the upper surface of the epitaxial layer 100, a portion of the upper surface of the second well 110b, and a portion of the upper surface of the second conductive region 120b. The gate oxide layer 140 may include, for example, silicon oxide (SiO₂) or a high-k material.

The polysilicon layer 150 may be formed on the gate oxide layer 140 as a conductive layer used as a gate electrode. The polysilicon layer 150 may include, for example, doped polysilicon and may control current by transmitting a gate signal to the channel.

The field oxide layer 160 has an insulating function and may be formed on a portion of the upper surfaces of the first conductive region 120a and the second conductive region 120b and on the upper surface of the polysilicon layer 150.

The metal layer 170 is a conductive layer forming an electrode and may include, for example, a metal such as aluminum (Al), nickel (Ni), or titanium (Ti).

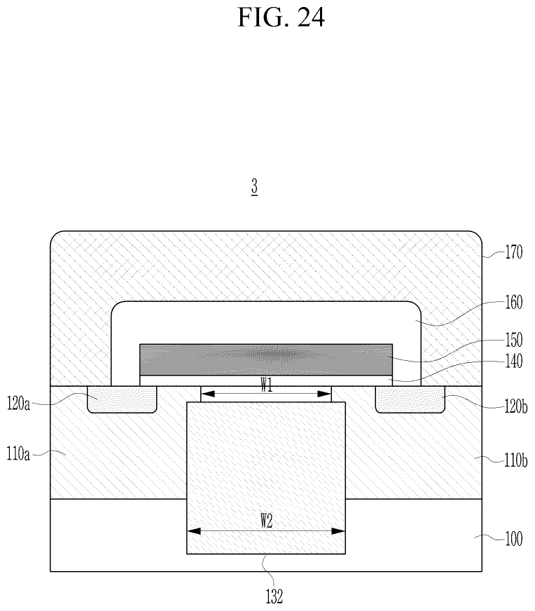

FIG. 24 is a drawing for describing a semiconductor device according to an embodiment.

Referring to FIG. 24, a semiconductor device 3 according to an embodiment may include the epitaxial layer 100, the wells 110a and 110b, the conductive regions 120a and 120b, a JFET region 132, the gate oxide layer 140, the polysilicon layer 150, the field oxide layer 160, and the metal layer 170.

The epitaxial layer 100 is a monocrystalline semiconductor layer formed on the semiconductor substrate and may have the first conductivity type. For example, the epitaxial layer 100 may be a low-concentration n-type epitaxial layer formed on the semiconductor substrate and may function as a drift region of the semiconductor device 1. The thickness and doping concentration of the epitaxial layer 100 may be designed in consideration of the breakdown voltage of the target semiconductor device 1, etc.

The wells 110a and 110b are formed on the upper portion of the epitaxial layer 100 and may have a second conductivity type different from the first conductivity type. For example, the wells 110a and 110b may be formed as p-wells. As illustrated, the wells 110a and 110b may include a first well 110a and a second well 110b formed to be spaced apart from the first well 110a.

The conductive regions 120a and 120b are formed inside the wells 110a and 110b, and may have the first conductivity type. For example, the conductive regions 120a and 120b may have an n+type. The conductive regions 120a and 120b may correspond to a portion in the semiconductor device 1 where a channel is formed in which electron movement is activated or blocked, depending on the gate voltage.

The JFET region 132 may be formed between the first well 110a and the second well 110b. Specifically, the JFET region 132 is formed between the first well 110a and the second well 110b, and the lower surface thereof may be formed lower than the lower surface of the first well 110a and the lower surface of the second well 110b.

A width W4 of the JFET region 132 may be formed to be larger than the distance W1 between the first well 110a and the second well 110b. Therefore, unlike the semiconductor device 1 of FIG. 1, no intermediate region is defined between the first well 110a and the JFET region 132 and between the second well 110b and the JFET region 132. Additionally, the upper surface of the JFET region 132 may be formed lower than the upper surface of the epitaxial layer 100.

Unlike the semiconductor devices 1 and 2 of FIGS. 1 and 23, at least a portion of the JFET region 132 may be formed on the lower portion of the first well 110a and the second well 110b.

In some embodiments, the JFET region 132 may be formed through the channeling implant described with respect to FIG. 1, and the spacing of the photoresist may be arranged differently from the case of forming the JFET regions 130 and 131 of FIGS. 1 and 23 to secure the width W4 of the JFET region 132.

The gate oxide layer 140, the polysilicon layer 150, the field oxide layer 160, and the metal layer 170 may be formed on the upper surface of the epitaxial layer 100 in which the JFET region 132 is defined, on the upper surface of the wells 110a and 110b, and on the upper surface of the conductive regions 120a and 120b.

The gate oxide layer 140 may have a function of forming a channel using an electric field effect with an insulating layer between the gate electrode and the channel, and may be formed over a portion of the upper surface of the first conductive region 120a, a portion of the upper surface of the first well 110a, a portion of the upper surface of the epitaxial layer 100, a portion of the upper surface of the second well 110b, and a portion of the upper surface of the second conductive region 120b. The gate oxide layer 140 may include, for example, silicon oxide (SiO₂) or a high-k material.

The polysilicon layer 150 may be formed on the gate oxide layer 140 as a conductive layer used as a gate electrode. The polysilicon layer 150 may include, for example, doped polysilicon, and may control current by transmitting a gate signal to the channel.

The field oxide layer 160 has an insulating function and may be formed on a portion of the upper surfaces of the first conductive region 120a and the second conductive region 120b and on the upper surface of the polysilicon layer 150.

The metal layer 170 is a conductive layer forming an electrode and may include, for example, a metal such as aluminum (Al), nickel (Ni), or titanium (Ti).

According to the embodiments described above, by adopting a structure in which the JFET region is formed at a high concentration in a region deeper than the p-well, it is possible to prevent the problem of increasing JFET resistance while reducing cell pitch and reduce on-resistance. While simply reducing cell spacing without considering the JFET region will result in a relative increase in JFET resistance, making it difficult to lower on-resistance, structures according to embodiments allow for high integration while maintaining low on-resistance.

In addition, among the parasitic capacitances formed in vertical power MOSFETs, the gate-drain capacitance increases in proportion to the width of the JFET region, which affects switching speed. According to embodiments, by optimizing the width of the JFET region and reducing the value of the gate-drain capacitance, the switching loss occurring during turn-on/turn-off may be significantly improved. This may improve the efficiency of electric power conversion devices that require high-speed switching characteristics.

In addition, with the alternating operation of the high-side and low-side MOSFETs in a half-bridge inverter circuit, if both devices are turned on at the same time, there is a risk of high current flowing through the device, causing it to break down. In general, when a device fails in a short-circuit condition, the gate oxide layer is damaged, causing a gate-to-source short circuit, which may lead to thermal runaway. In the structure according to the embodiments, heat generation may be reduced by limiting the maximum current that can flow through a narrow JFET region during a short circuit, and thus the short-circuit withstand time (SCWT) is increased by about 15%, allowing the device to withstand a short circuit for a longer time.

While the embodiments of the present disclosure have been described in detail, it is to be understood that the disclosure is not limited to the disclosed embodiments, but on the contrary, is intended to cover various modifications and equivalent arrangements included within the spirit and scope of the appended claims.

What is claimed is:

1. A semiconductor device, comprising:
an epitaxial layer having a first conductivity type;
a first well formed on the upper portion of the epitaxial layer and having a second conductivity type different from the first conductivity type;
a second well formed on the upper portion of the epitaxial layer and spaced apart from the first well and having the second conductivity type; and
a junction field-effect transistor (JFET) region formed between the first well and the second well, the lower surface of which is formed lower than the lower surface of the first well and the lower surface of the second well.

2. The semiconductor device of claim 1, wherein
the JFET region is formed to be spaced apart from the first well and the second well.

3. The semiconductor device of claim 1, further comprising:
a first intermediate region defined on the epitaxial layer between the first well and the JFET region; and
a second intermediate region defined on the epitaxial layer between the second well and the JFET region.

4. The semiconductor device of claim 3, wherein
the width of the JFET region is smaller than the distance between the first well and the second well,
and greater than the width of the first intermediate region or the second intermediate region.

5. The semiconductor device of claim 1, wherein
the JFET region is not formed in the lower portion of the first well and the second well.

6. The semiconductor device of claim 1, wherein
the width of the JFET region is equal to the distance between the first well and the second well,
and the JFET region is not formed in the lower portion of the first well and the second well.

7. The semiconductor device of claim 1, wherein
the width of the JFET region is greater than the distance between the first well and the second well,
and at least a portion of the JFET region is formed on the lower portion of the first well and the second well.

8. The semiconductor device of claim 1, wherein
the upper surface of the JFET region is formed lower than the upper surface of the epitaxial layer.

9. The semiconductor device of claim 1, wherein
the JFET region is formed through performing a channeling implant by tilting a wafer on which photoresists are formed at a spacing smaller than the distance between the first well and the second well by a predetermined angle.

10. The semiconductor device of claim 9, wherein
the predetermined angle is 3 degrees or more and 5 degrees or less.

11. A manufacturing method of a semiconductor, comprising:
forming an epitaxial layer having a first conductivity type;
forming a first well having a second conductivity type different from the first conductivity type on the upper portion of the epitaxial layer, and a second well spaced apart from the first well and having the second conductivity type; and
forming a junction field-effect transistor (JFET) region between the first well and the second well such that the lower surface thereof is lower than the lower surface of the first well and the lower surface of the second well.

12. The manufacturing method of the semiconductor of claim 11, wherein
the forming of the JFET region comprises tilting a wafer on which photoresists are formed at a spacing smaller than the distance between the first well and the second well by a predetermined angle and performing a channeling implant.

13. The manufacturing method of the semiconductor of claim 12, wherein
the predetermined angle is 3 degrees or more and 5 degrees or less.

14. The manufacturing method of the semiconductor of claim 11, wherein
the JFET region is formed to be spaced apart from the first well and the second well.

15. The manufacturing method of the semiconductor of claim 11, wherein
a first intermediate region is defined on the epitaxial layer between the first well and the JFET region,
and a second intermediate region is defined on the epitaxial layer between the second well and the JFET region.

16. The manufacturing method of the semiconductor of claim 15, wherein
the width of the JFET region is smaller than the distance between the first well and the second well,
and greater than width of the first intermediate region or the second intermediate region.

17. The manufacturing method of the semiconductor of claim 11, wherein
the JFET region is not formed in the lower portion of the first well and the second well.

18. The manufacturing method of the semiconductor of claim 11, wherein
the width of the JFET region is equal to the distance between the first well and the second well,
and the JFET region is not formed in the lower portion of the first well and the second well.

19. The manufacturing method of the semiconductor of claim 11, wherein
the width of the JFET region is greater than the distance between the first well and the second well,
and at least a portion of the JFET region is formed on the lower portion of the first well and the second well.

20. The manufacturing method of the semiconductor of claim 11, wherein
the upper surface of the JFET region is formed lower than the upper surface of the epitaxial layer.
